(19) United States
(12) Patent Application Publication
(10) Pub. No.: US 2026/0173745 A1
(43) Pub. Date: Jun. 18, 2026

(54) DISPLAY DEVICE AND REPAIRING METHOD THEREOF

(71) Applicant: LG Display Co., Ltd., Seoul (KR)

(72) Inventors: Yeonjun Oh, Incheon (KR); SungJoon Min, Goyang-si (KR); Dojoong Kim, Seoul (KR); JunHyuk Song, Seoul (KR); Taehyun Kim, Uijeongbu-si (KR)

(73) Assignee: LG Display Co., Ltd., Seoul (KR)

(21) Appl. No.: 19/365,099

(22) Filed: Oct. 21, 2025

(30) Foreign Application Priority Data
Dec. 13, 2024 (KR) 10-2024-0185641

(51) Int. Cl. H10K 71/00; H10H 29/01; H10H 29/49; H10K 59/12; H10K 59/131; H10K 59/80; H10K 59/88; H10K 77/10

(52) U.S. Cl. CPC H10K 71/861; H10H 29/012; H10H 29/49; H10K 59/1201; H10K 59/131; H10K 59/871; H10K 59/88; H10K 77/111

(57) ABSTRACT

The present application provides a display device and a repairing method thereof. According to an aspect of the present disclosure, a display device includes a lower substrate which is divided into an active area and a non-active area and is stretchable; a plurality of pixels on the active area of the lower substrate; a plurality of connection lines on the lower substrate and connected respectively to the plurality of pixels; and at least one repair line connected in parallel with at least one of the plurality of connection lines.

### CROSS-REFERENCE TO RELATED APPLICATION

This application claims the priority of Korean Patent Application No. 10-2024-0185641, filed on Dec. 13, 2024, in the Korean Intellectual Property Office, the entire disclosure of which is expressly incorporated into the present application by reference as if fully set forth herein.

### BACKGROUND

### Technical Field

The present disclosure relates to a display device and a repairing method thereof, and particularly to, for example, without limitation, a stretchable display device which is stretchable and a repairing method thereof.

### Description of the Related Art

Display devices used for a monitor of a computer, a television, or a cellular phone include, without limitation, an organic light emitting display device (OLED) which is a self-emitting device and a liquid crystal display device (LCD) which requires a separate light source.

An applicable range of the display devices is diversified to personal digital assistants as well as monitors of computers and televisions, and a display device with a large display area and reduced volume and weight is being studied.

Recently, a display device which is manufactured by forming a display unit and a wiring line on a flexible substrate, such as plastic which is a flexible material, so as to be stretchable in a specific direction and changed in various forms is getting attention as a next generation display device.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

An object of the present disclosure is to provide a display device which can repair a defect due to a disconnection in the display device and a repairing method thereof.

Another object of the present disclosure is to provide a display device in which a function of a damaged data line or scan line is replaced by means of the repair to maintain a normal operation.

Objects of the present disclosure are not limited to the above-mentioned objects, and other objects, which are not mentioned above, can be clearly understood by those skilled in the art from the following descriptions.

To achieve the above and other objects, and according to an aspect of the present disclosure, a display device includes a lower substrate which is divided into an active area and a non-active area and is stretchable; a plurality of pixels on the active area of the lower substrate; a plurality of connection lines on the lower substrate and connected respectively to the plurality of pixels; and at least one repair line connected in parallel with at least one of the plurality of connection lines to repair the disconnection of the connection line.

To achieve the above and other objects, and according to another aspect of the present disclosure, a repairing method of a display device may include: forming a support pattern and a connection electrode on a connection line which is defective, among the plurality of connection lines; forming an adhesive pattern on the connection electrode; bonding a repair substrate on which a substrate, a sacrificial layer, a cover pattern, and a repair line are sequentially laminated onto the adhesive pattern; and lifting-off the repair substrate to place the cover pattern and the repair line on the adhesive pattern by selectively removing the sacrificial layer.

Other detailed matters of various example embodiments are included in the detailed description and the drawings.

According to example embodiments of the present disclosure, a repair line which is connected in parallel with a connection line is additionally formed to effectively supplement the disconnection of the connection line. By doing this, the reliability and the stability of the display device may be improved.

According to example embodiments of the present disclosure, a repaired circuit may be protected from external shocks, moisture, and dusts and a long-term durability of the display device may be ensured, by means of a support pattern, a sealing layer, and a cover pattern.

The effects according to the present disclosure are not limited to the contents exemplified above, and various additional effects may be attained from the present disclosure.

Other systems, methods, features, and advantages will be, or will become, apparent to one with skill in the art upon examination of the following figures and detailed description. It is intended that all such additional systems, methods, features, and advantages be included within this description, be within the scope of the present disclosure, and be protected by the following claims. Nothing in this section should be taken as a limitation on those claims. Further aspects and advantages are discussed below in conjunction with example embodiments of the disclosure.

It is to be understood that both the foregoing general description and the following detailed description are by way of example and explanatory and are intended to provide further explanation of the inventive concepts as claimed.

### BRIEF DESCRIPTION OF DRAWINGS

The above and other aspects, features, and other advantages of the present disclosure will be more clearly understood from the following detailed description taken in conjunction with the accompanying drawings, in which:

FIG. 1 is a plan view illustrating a display device according to example embodiments of the present disclosure;

FIG. 2 is an enlarged plan view illustrating an example of part A of FIG. 1;

FIG. 3 is a cross-sectional view illustrating an example taken along the line III-III′ in FIG. 2;

FIG. 4 is a flowchart illustrating a repairing method of a display device according to example embodiments of the present disclosure; and

FIGS. 5A to 5E are cross-sectional views illustrating steps of a repairing method of a display device according to example embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, where a detailed description of well-known functions or configurations related to this document may unnecessarily obscure a feature or aspect of the present disclosure, the detailed description thereof may be omitted or may be briefly provided.

Advantages and characteristics of the present disclosure and a method of achieving the advantages and characteristics will be clear by referring to example embodiments described below in detail together with the accompanying drawings. However, the present disclosure is not limited to the example embodiments disclosed herein but may be implemented in various other forms. The example embodiments are provided by way of example only so that those skilled in the art can more fully understand the disclosures of the present disclosure and the scope of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example, and the sequence of steps and/or operations is not limited to that set forth herein and may be changed as is known in the art, with the exception of steps and/or operations necessarily occurring in a particular order. Like reference numerals generally designate like elements throughout. Names of the respective elements used in the following explanations are selected only for convenience of writing the specification and may thus be different from those used in actual products.

The shapes, sizes, ratios, angles, numbers, and the like illustrated in the accompanying drawings for describing the example embodiments of the present disclosure may be merely examples, and thus the present disclosure is not limited thereto. Like reference numerals generally denote like elements throughout the specification. Further, in the following description of the present disclosure, a detailed explanation of known related technologies may be omitted or may be briefly provided to avoid unnecessarily obscuring the subject matter of the present disclosure. The terms such as “including,” “having,” and “consist of,” if used herein, are generally intended to allow other components to be added unless the terms are used with a more limiting term like “only”. Any references to singular may include plural, and vice versa, unless expressly stated otherwise.

Any implementation described herein as an “example” is not necessarily to be construed as preferred or advantageous over other implementations.

Components are to be interpreted to include an ordinary error range even if not expressly stated.

Where two elements are described as “connected” or “coupled,” unless a more limiting term like “directly” or “immediately” is used, the connection or coupling may include indirect connections or couplings through one or more other components positioned between the two elements.

Although the terms “first”, “second”, and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

The features of various embodiments of the present disclosure can be partially or entirely adhered to or combined with each other and can be interlocked and operated in technically various ways, and the embodiments can be carried out independently of or in association with each other.

It will be apparent to those skilled in the art that various modifications and variations can be made to the embodiments of the present disclosure without departing from the technical idea or scope of the present disclosure. Thus, it is intended that the present disclosure cover the modifications and variations of this disclosure provided they come within the scope of the appended claims and their equivalents.

Hereinafter, various example embodiments of the present disclosure will be described in detail with reference to accompanying drawings.

A display device according to example embodiments of the present disclosure is a display device which is capable of displaying images even in a bent or extended state and may also be referred to as a stretchable display device, a flexible display device and an extendable display device. As compared with the general display devices of the related art, the display device may have not only a high flexibility, but also stretchability. Therefore, the user may bend or extend a display device, and a shape of a display device may be freely changed in accordance with manipulation of a user. For example, when the user pulls the display device by holding ends of the display device, the display device may be extended to the pulling direction of the user. Alternatively, when the user disposes the display device on an outer surface which is not flat, the display device may be disposed to be bent in accordance with the shape of the outer surface of the wall. Further, when a force applied by the user is removed, the display device may return to its original shape.

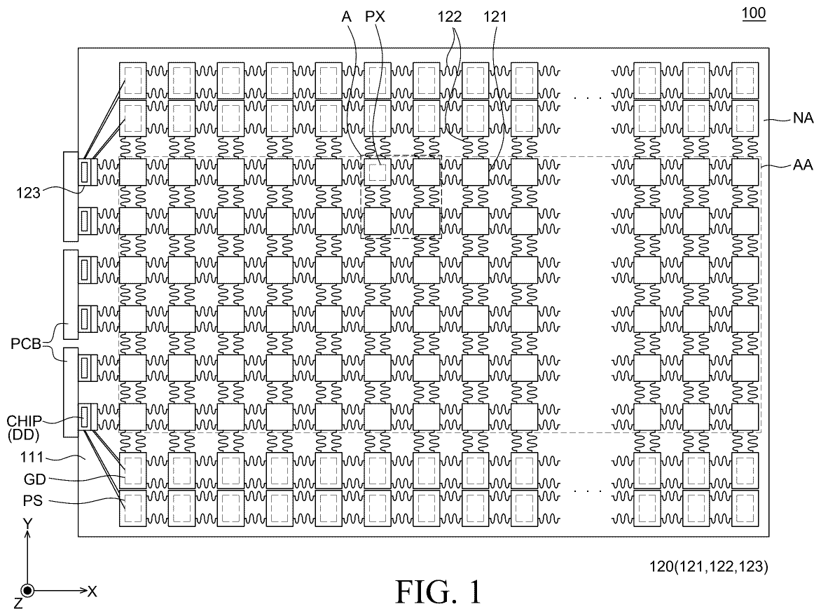

FIG. 1 is a plan view illustrating a display device according to example embodiments of the present disclosure.

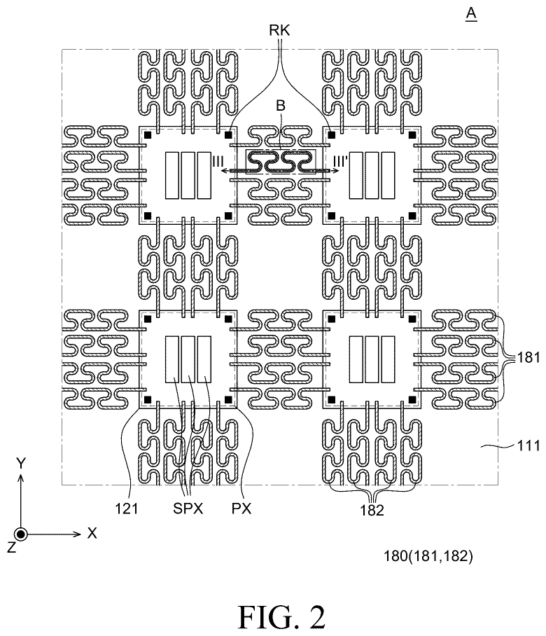

FIG. 2 is an enlarged plan view illustrating an example of part A of FIG. 1.

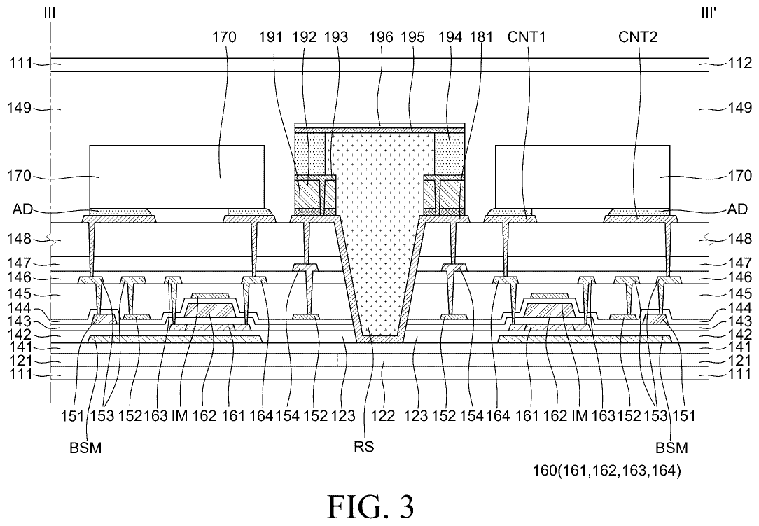

FIG. 3 is a cross-sectional view illustrating an example taken along the line III-III′ in FIG. 2.

As shown in FIG. 1, a display device 100 according to example embodiments of the present disclosure may include a lower substrate 111, a pattern layer 120, a plurality of pixels PX, a gate driver GD, a data driver DD, and a power supply PS. In an example embodiment, further as shown in FIG. 3, the display device 100 may further include a filling layer 149, an upper substrate 112, at least one support pattern 191, 192, a connection electrode 193, an adhesive pattern 194, a repair line 195, and a cover pattern 196.

The lower substrate 111 may support various components of the display device 100 and the upper substrate 112 may cover various components of the display device 100.

In an example embodiment, the lower substrate 111 and the upper substrate 112 which are flexible substrates may include an insulating material which is bendable or extendable.

A modulus of elasticity of each of the lower substrate 111 and the upper substrate 112 may be several MPa to several hundreds of MPa. According to the example embodiment, a ductile breaking rate of each of the lower substrate 111 and the upper substrate 112 may be 100% or higher. Here, the ductile breaking rate refers to a stretching rate at a timing when an object to be stretched is broken or cracked.

The lower substrate 111 may include an active area AA in which images are displayed and a non-active area NA excluding the active area AA. For example, on the active area AA, a plurality of pixels PX each including a display element and a circuit element may be disposed and on the non-active area NA, a gate driver GD and a power supply PS for driving the plurality of pixels PX disposed in the active area AA may be disposed.

The pattern layer 120 may be disposed on the lower substrate 111. As shown in FIG. 1, the pattern layer 120 may include a plurality of plate patterns 121 which is disposed as islands which are spaced apart from each other and a plurality of line patterns 122 which connects the plurality of plate patterns 121. Each of the plurality of plate patterns 121 and the plurality of line patterns 122 may be disposed on the active area AA and the non-active area NA of the lower substrate 111. On the plurality of plate patterns 121 disposed in the active area AA, a plurality of pixels PX may be formed and on the plurality of plate patterns 121 disposed in the non-active area NA, a gate driver GD and a power supply PS may be formed.

Further, in FIGS. 1 and 2, it is illustrated that the plurality of plate patterns 121 has a quadrangular shape, but it is not limited thereto.

In an example embodiment, the plurality of line patterns 122 may have a wavy shape (for example, a sine wave shape), but is not limited thereto. Each of the plurality of line patterns 122 may have various shapes to extend in a zigzag shape or extend to be a plurality of rhombic substrates which is connected at their vertices.

In an example embodiment, the pattern layer 120 may further include a plurality of pad patterns 123. A driving chip CHIP which is disposed between the lower substrate 111 and the upper substrate 112 and a plurality of pads connected thereto may be disposed on the plurality of pad patterns 123.

As shown in FIG. 1, the plurality of pad patterns 123 may be disposed on the non-active area NA between the lower substrate 111 and the upper substrate 112. For example, the driving chip CHIP disposed on the pad pattern 123 may be disposed on the non-active area NA between the active area AA and the printed circuit board PCB, for example, on the pad area so as to be connected to the plurality of pixels PX, the gate driver GD, and the power supply PS disposed on the printed circuit board PCB and the plurality of plate patterns 121 through the plurality of pads.

Further, as illustrated in FIG. 1, each of the plurality of pad patterns 123 may have a rectangular shape having one pair of short sides extending along the first direction X and one pair of long sides extending along the second direction Y, but this is just illustrative. Therefore, the example embodiment of the present disclosure is not limited thereto.

In an example embodiment, the plurality of plate patterns 121, the plurality of line patterns 122, and the plurality of pad patterns 123 may be rigid patterns. For example, the plurality of plate patterns 121, the plurality of line patterns 122, and the plurality of pad patterns 123 may be more rigid than the lower substrate 111 and the upper substrate 112. Accordingly, moduli of elasticity and hardnesses of the plurality of plate patterns 121, the plurality of line patterns 122, and the plurality of pad patterns 123 may be higher than the moduli of elasticity and the hardnesses of the lower substrate 111 and the upper substrate 112. For example, moduli of elasticity of the plurality of plate patterns 121, the plurality of line patterns 122, and the plurality of pad patterns 123 may be 1000 times higher than the moduli of elasticity of the lower substrate 111 and the upper substrate 112, but it is illustrative and the example embodiment of the present disclosure is not limited thereto.

In an example embodiment, each of the plurality of plate patterns 121, the plurality of line patterns 122, and the plurality of pad patterns 123 may include a plastic material having a lower flexibility than the lower substrate 111 and the upper substrate 112.

The gate driver GD may supply a gate voltage to the plurality of pixels PX disposed in the active area AA. The gate driver GD may include a plurality of stages formed on the plurality of plate patterns 121 disposed in the non-active area NA and each stage included in the gate driver GD may be electrically connected to each other by means of the plurality of gate connection lines. Accordingly, a gate signal output from any one of stages may be transmitted to the other stage. Each stage may sequentially supply the gate signal to the plurality of pixels PX connected to each stage.

The power supply PS is connected to the gate driver GD to supply a gate driving voltage and a gate clock voltage to the gate driver GD. Further, the power supply PS is connected to the plurality of pixels PX to supply a pixel driving voltage to each of the plurality of pixels PX.

The printed circuit board PCB includes a controller, such as an IC chip or a circuit unit and/or a memory or a processor to transmit a signal and a voltage for driving the display element from the controller to the display element. The printed circuit board PCB may include a stretching area and a non-stretching area to ensure stretchability. For example, in the non-stretching area, an IC chip, a circuit unit, a memory, and a processor may be mounted and in the stretching area, wiring lines which are electrically connected to the IC chip, the circuit unit, the memory, and the processor may be disposed.

The driving chip CHIP disposed on the plurality of pad patterns 123 may include a data driver DD. For example, the data driver DD is configured as an IC chip so that it may also be referred to as a data integrated circuit D-IC. The data driver DD may supply a data voltage to the plurality of pixels PX disposed in the active area AA.

As shown in FIGS. 2 and 3, a pixel PX including the plurality of sub pixels SPX may be disposed in the plate pattern 121 disposed on the lower substrate 111. Each of the plurality of sub pixels SPX may include a light emitting element 170 which is a display element and a driving transistor 160 which drives the light emitting element 170. The light emitting element 170 may be any one of LED or a micro LED. However, an organic light emitting diode (OLED) may also be used as the light emitting element 170, but is not limited thereto. Further, the plurality of sub pixels SPX may include a red sub pixel, a green sub pixel, and a blue sub pixel, but is not limited thereto and colors of the plurality of sub pixels SPX may be modified to various colors as needed.

The sub pixel SPX and the light emitting element 170 may be connected to a plurality of connection lines 180.

To be more specific, the plurality of sub pixels SPX may be connected to a plurality of connection lines 181 and 182. For example, the plurality of sub pixels SPX may be electrically connected to the first connection line 181 extending in the first direction X and may be electrically connected to the second connection line 182 extending in the second direction Y.

Hereinafter, a cross-sectional structure of the active area AA will be described in more detail with reference to FIG. 3.

First, a multi-buffer layer 141 is disposed on the plurality of plate patterns 121 and the plurality of line patterns 122, and an active buffer layer 142 is disposed on the multi-buffer layer 141. The multi-buffer layer 141 and the active buffer layer 142 reduce the permeation of moisture or impurities from the outside of the lower substrate 111 and the plate pattern 121 to protect various components of the display device 100. The multi-buffer layer 141 and the active buffer layer 142 may be formed of an insulating material. For example, the multi-buffer layer 141 and the active buffer layer 142 may be configured by a single layer or a double layer of silicon nitride (SiNx), silicon oxide (SiOx), and silicon oxynitride (SiON), but are not limited thereto. However, the multi-buffer layer 141 and the active buffer layer 142 may be omitted depending on a structure or a characteristic of the display device 100.

A light shielding layer BSM may be disposed between the multi-buffer layer 141 and the active buffer layer 142. The light shielding layer BSM blocks light which is incident to an active layer 161 of the driving transistor 160 to be described below to reduce or minimize a leakage current of the driving transistor 160. For example, the light shielding layer BSM may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The driving transistor 160 is disposed on the active buffer layer 142. The driving transistor 160 includes an active layer 161, a gate electrode 162, a source electrode 163, and a drain electrode 164.

The active layer 161 is disposed on the active buffer layer 142. The active layer 161 may be formed of a semiconductor material, such as an oxide semiconductor, amorphous silicon, or polysilicon, but is not limited thereto.

A gate insulating layer 143 is disposed on the active layer 161. The gate insulating layer 143 is an insulating layer which insulates the active layer 161 from the gate electrode 162 and may be configured by a single layer or a double layer of silicon oxide (SiOx) or silicon nitride (SiNx), but is not limited thereto.

The gate electrode 162 is disposed on the gate insulating layer 143. The gate electrode 162 may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

A first interlayer insulating layer 144 is disposed on the gate electrode 162 and a second interlayer insulating layer 145 is disposed on the first interlayer insulating layer 144. The first interlayer insulating layer 144 and the second interlayer insulating layer 145 are insulating layers which protect components therebelow and may be configured by a single layer or a double layer of silicon oxide (SiOx) or silicon nitride (SiNx), but are not limited thereto.

A source electrode 163 and a drain electrode 164 are disposed on the second interlayer insulating layer 145. The source electrode 163 and the drain electrode 164 may be electrically connected to the active layer 161 through contact holes formed in the second interlayer insulating layer 145, the first interlayer insulating layer 144, and the gate insulating layer 143. The source electrode 163 and the drain electrode 164 may be configured by a single layer or a multi-layered structure of a conductive material, such as copper (Cu), aluminum (Al), molybdenum (Mo), nickel (Ni), titanium (Ti), chrome (Cr), or an alloy thereof, but are not limited thereto.

Next, an intermediate metal layer IM is disposed on the first interlayer insulating layer 144. The intermediate metal layer IM overlaps the gate electrode 162 of the driving transistor 160. The intermediate metal layer IM and the gate electrode 162 of the driving transistor 160 overlap each other to form a storage capacitor. However, the intermediate metal layer IM overlaps the other electrode to form a storage capacitor, but a placement area of the intermediate metal layer IM is not limited thereto.

A third interlayer insulating layer 146 is disposed on the driving transistor 160. The third interlayer insulating layer 146 is an insulating layer which protects components below the third interlayer insulating layer 146 and may be configured by a single layer or a double layer of silicon oxide (SiOx) or silicon nitride (SiNx), but is not limited thereto.

A passivation layer 147 is disposed on the third interlayer insulating layer 146. The passivation layer 147 is an insulating layer which protects components below the passivation layer 147 and may be configured by a single layer or a double layer of silicon oxide (SiOx) or silicon nitride (SiNx), but is not limited thereto.

A planarization layer 148 is disposed on the passivation layer 147. The planarization layer 148 may planarize an upper portion of the plate pattern 121 on which a plurality of conductive layers, the driving transistor 160, and a plurality of wiring lines are disposed. The planarization layer 148 may be configured by a single layer or a plurality of layers and may be formed of an organic material. For example, the planarization layer 148 may be configured by a single layer or a double layer, and for example, may be formed of photoresist or an acrylic organic material, but is not limited thereto.

In the meantime, the gate insulating layer 143, the first interlayer insulating layer 144, the second interlayer insulating layer 145, the third interlayer insulating layer 146, and the passivation layer 147 are patterned to be formed only in an area overlapping the plurality of plate patterns 121. For example, at least any one of the gate insulating layer 143, the first interlayer insulating layer 144, the second interlayer insulating layer 145, the third interlayer insulating layer 146, and the passivation layer 147 may be formed of an inorganic insulating material, among insulating materials, and is easily damaged, such as crack, during the process of stretching the display device 100. Therefore, the multi-buffer layer 141, the active buffer layer 142, the gate insulating layer 143, the first interlayer insulating layer 144, the second interlayer insulating layer 145, the third interlayer insulating layer 146, and the passivation layer 147 are not formed in an area between the plurality of plate patterns 121, but are patterned to have a shape of the plurality of plate patterns 121 to be formed only above the plurality of plate patterns 121.

A first connection pad CNT1 and a second connection pad CNT2 are disposed on the planarization layer 148. The first connection pad CNT1 and the second connection pad CNT2 are electrodes which electrically connect the light emitting element 170 to the driving transistor 160 and the power line. For example, the first connection pad CNT1 may electrically connect a p-electrode 175 of the light emitting element 170 to the driving transistor 160 and the second connection pad CNT2 may electrically connect an n-electrode 174 of the light emitting element 170 to the power line.

An adhesive layer AD is disposed on the first connection pad CNT1 and the second connection pad CNT2. The adhesive layer AD may be disposed on the upper surfaces of the first connection pad CNT1 and the second connection pad CNT2 and between the first connection pad CNT1 and the second connection pad CNT2. The light emitting element 170 may be bonded onto the first connection pad CNT1 and the second connection pad CNT2 by the adhesive layer AD.

The adhesive layer AD may be a conductive adhesive pattern in which conductive balls are dispersed in an insulating base member. Therefore, when heat or pressure is applied to the adhesive layer AD, the conductive balls are electrically connected in a portion applied with the heat or pressure to have a conductive property and an area which is not pressurized may have an insulation property. For example, after applying the adhesive layer AD on the first connection pad CNT1 and the second connection pad CNT2 using an inkjet method, the light emitting element 170 is transferred onto the adhesive layer AD and then the light emitting element 170 is pressurized and heated. By doing this, the first connection pad CNT1 and the p-electrode of the light emitting element 170 and the second connection pad CNT2 and the n-electrode of the light emitting element 170 may be electrically connected.

Even though it is not illustrated in the drawing, a bank may be further disposed on the planarization layer 148. The bank is a component which divides adjacent sub pixels SPX. The bank is disposed between the plurality of light emitting elements 170 to suppress color mixture.

In the meantime, various conductive layers may be further disposed on the plate pattern 121. For example, a first conductive layer 151 may be disposed on the gate insulating layer 143 and a plurality of second conductive layers 152 may be disposed on the first interlayer insulating layer 144. A plurality of third conductive layers 153 may be disposed on the second interlayer insulating layer 145 and a fourth conductive layer 154 may be disposed on the third interlayer insulating layer 146. At least one of the plurality of conductive layers may be omitted and each of the plurality of conductive layers may be included in any one of the plurality of wiring lines, a plurality of transistors, and a plurality of capacitors.

For example, as illustrated in FIG. 3, the first conductive layer 151 may be connected to a high potential power line and the first conductive layer 151 may be connected to the second connection pad CNT2 through the third conductive layer 153. Therefore, a high potential power may be supplied to the second connection pad CNT2.

A filling layer 190 is disposed between the lower substrate 111 and the upper substrate 112. The filling layer 190 is disposed on the entire surface of the lower substrate 111 to fill a space between the components disposed on the upper substrate 112 and the lower substrate 111. The filling layer 190 may be configured by a curable adhesive. Specifically, the material which configures the filling layer 190 is coated on the entire surface of the lower substrate 111 and then is hardened so that the filling layer 190 may be disposed between the configurations disposed on the upper substrate 112 and the lower substrate 111.

Next, the plurality of connection lines 180 extends onto the plate pattern 121 from the line pattern 122 to be connected to the plurality of wiring lines on the plate pattern 121. For example, the first connection line 181 may extend onto the planarization layer 148 of the plate pattern 121 from the line pattern 122. The first connection line 181 may be connected to a reference line and a plurality of data lines and the second connection line 182 may be connected to a low potential power line, a scan line, an emission control line, and a high potential power line.

In the meantime, in the case of a general display device, various wiring lines such as a plurality of scan lines and a plurality of data lines extend between the plurality of sub pixels in a straight line shape and the plurality of sub pixels is connected to one signal line. Therefore, in the general display device, various wiring lines, such as a scan line, a data line, a power line, and a reference line, extend from one side to the other side of the display device without being disconnected on the substrate.

In contrast, in the case of the display device according to the example embodiment of the present disclosure, various straight wiring lines, such as a scan line, a data line, a power line, and a reference line, which seem to be used for the general display device, are disposed only on the plurality of plate patterns. That is, in the display device according to the example embodiment of the present disclosure, a straight wiring line is disposed only on the plurality of plate patterns 121. In the display device according to the example embodiment of the present disclosure, the wiring lines on two adjacent plate patterns 121 may be connected by the plurality of connection lines 180. Accordingly, the plurality of connection lines 180 electrically connects wiring lines on two adjacent plate patterns 121.

In the meantime, in the display device according to the example embodiment of the present disclosure, a defect of the connection line may be caused due to various causes. Due to a step between the plate pattern 121 and the line pattern 122, a defect that the connection line is disconnected, a defect that a connection line disposed on the line pattern 122 is disconnected during the formation process of the line pattern 122, or a defect of the connection line due to the oxidation of the connection line may be caused.

For example, as shown in FIG. 2, a defect of the connection line 180 disposed in an area B, among the plurality of connection lines, is generated so that the connection line 180 disposed in the area B may be disconnected.

Therefore, the display device according to the example embodiment of the present disclosure may additionally include a repair line for repairing a disconnected connection line.

Specifically, as shown in FIG. 3, the display device according to the example embodiment of the present disclosure may further include support patterns 191 and 192, a connection electrode 193, an adhesive pattern 194, a repair line 195, a cover pattern 196, and a sealing layer RS, to repair the disconnected connection line.

The support patterns 191 and 192 mechanically support the connection electrode 193 to provide a stability of the structure and protect the connection electrode 193 so as not to be damaged even during the physical shock or stretching of a display substrate. The support patterns 191 and 192 are disposed above the connection line 181 and a hole is formed therein so that the connection electrode 193 is inserted therein to enable electrical connection between the connection line 181 and the repair line 195. The support patterns 191 and 192 may include a first support pattern 191 disposed on an upper surface of the connection line 181 and a second support pattern 192 disposed on the first support pattern 191. The first support pattern 191 may be configured by a single layer or a double layer of silicon nitride (SiNx), silicon oxide (SiOx), and silicon oxynitride (SiON), but is not limited thereto. The second support pattern 192 may be formed of photoresist or an acrylic organic material, but is not limited thereto. Such support patterns 191 and 192 maintain the stability of the structure of the display device and suppress the damage of the wiring line during the stretching, enabling precise alignment with the connection electrode 193 to increase the reliability of the electrical connection of the connection electrode 193 and the connection line 181. Due to the heights of the support patterns 191 and 192, an upper surface of the second support pattern 192 may be higher than an upper surface of the light emitting element 170. Therefore, during the repair process of the present disclosure, the damage of the light emitting element 170 may be reduced or minimized due to the height difference of the cover pattern 196 and the light emitting element 170.

The connection electrode 193 provides an electrical connection between the connection line 181 and the repair line 195 to facilitate the signal transmission. The connection electrode 193 is disposed through holes formed in the support patterns 191 and 192 and is electrically connected from the upper surface of the connection line 181 to a lower surface of the repair line 195. The connection electrode 193 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The connection electrode 193 is precisely formed with minute patterns to reduce a loss of an interlayer electric signal and ensure the stable connection. By doing this, the connection electrode 193 may significantly improve the reliability of the electrical connection and maintain a normal operation of the repair line 195.

The adhesive pattern 194 serves to physically and electrically couple the connection electrode 193 and the repair line 195 to provide a stable and solid electrical connection. The adhesive pattern 194 is disposed between the connection electrode 193 and the repair line 195. The adhesive pattern 194 may be a conductive adhesive pattern in which conductive balls are dispersed in an insulating base member. Therefore, the adhesive pattern 194 may provide a reliable electrical connection, increase the adhesive strength, and suppress the disconnection.

The repair line 195 serves to provide an alternative path when the connection line 181 is disconnected to maintain the reliability of the circuit. The repair line 195 is connected in parallel with the connection line 181 and is electrically connected to the connection line 181 through the connection electrode 193. The repair line 195 is generally configured by a metal material having an excellent electrical conductivity, such as copper (Cu), silver (Ag), or aluminum (Al), and enables stable electric signal transmission. For example, all at least one repair line 195, a connection electrode 193, and the plurality of connection lines 181 may be formed of the same or substantially same material. The display device according to the example embodiment of the present disclosure is designed to maintain a normal operation of the display device by replacing a function of a damaged data line or scan line. By doing this, the repair line 195 serves as an important component to reduce or minimize the defect due to the disconnection in the display device and significantly improve the reliability.

The cover pattern 196 covers the repair line 195 to protect the repair line from the physical damage and the external environment and provide the stability. The cover pattern 196 is formed with a structure which is disposed on the upper surface of the repair line 195 to cover upper portions of the circuit including the repair line. The cover pattern is configured by a material having excellent insulating property and durability, such as polyimide (PI) or indium tin oxide (ITO) to suppress the electrical interruption and provide resistance against the external shock. In the flexible display, a cover pattern is designed to protect the repair line 195 even during the bending or stretching of the substrate to maintain the stability of the display. By doing this, the cover pattern 196 serves as an important element which protects the circuit from the external shocks, dusts, and moisture and significantly improves the reliability and the durability of the display.

The cover pattern 196 covers the repair line 195 to protect the repair line from the physical damage and the external environment and provide the stability. The cover pattern 196 is formed with a structure which is disposed on the upper surface of the repair line 195 to cover the repair line 195. The cover pattern 196 is configured by a material having excellent insulating property and durability, such as polyimide (PI) or indium tin oxide (ITO) to not only suppress the electrical interruption and provide the resistance against the external shocks, but also improve a yield of the lift-off process during the repair process. In the display device according to the example embodiment of the present disclosure, a cover pattern 196 is designed to protect the repair line 195 even during the bending or stretching of the substrate to maintain the stability. By doing this, the cover pattern 196 serves as an important element which protects the circuit from the external shocks, dusts, and moisture and significantly improves the reliability and the durability of the display device.

Specifically, when the cover pattern 196 is formed of polyimide (PI), the mechanical reliability of the repair line 195 may be more effectively improved, but etching of the polyimide PI to form the cover pattern 196 may be necessary.

In contrast, when the cover pattern 196 is formed of indium tin oxide (ITO), it is advantageous in that the etching process is not necessary so that the manufacturing process is simplified, but an improvement rate of the mechanical reliability of the repair line 195 may be relatively degraded.

The sealing layer RS serves to protect a circuit including the connection line 181 and the repair line 195 from the external environment and provide a structural stability. The sealing layer RS is disposed between the connection line 181 and the repair line 195 and is disposed between the plurality of support patterns 191 and 192, the connection electrode 193, and the adhesive pattern 194. The sealing layer is generally configured by an organic material-based polymer or silica (SiO₂) and silicon nitride (SiN) which are inorganic materials, to provide excellent moisture resistance and durability. The sealing layer RS serves as an important element to protect an internal circuit from a shock during the repair process to significantly improve long-term reliability and durability of the display device.

The display device according to the example embodiment of the present disclosure further includes and repairs the support patterns 191 and 192, the connection electrode 193, the adhesive pattern 194, the repair line 195, the cover pattern 196, and the sealing layer RS to maintain the normal operation of the display device by replacing the function of the damaged data line or scan line. Therefore, in the display device according to the example embodiment of the present disclosure, the repair line 195 serves as an important component which repairs the defect due to the disconnection in the display device and significantly improves the reliability.

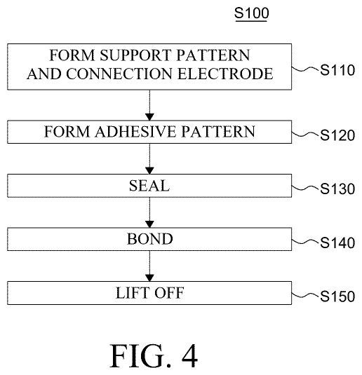

FIG. 4 is a flowchart illustrating a repairing method of a display device according to example embodiments of the present disclosure.

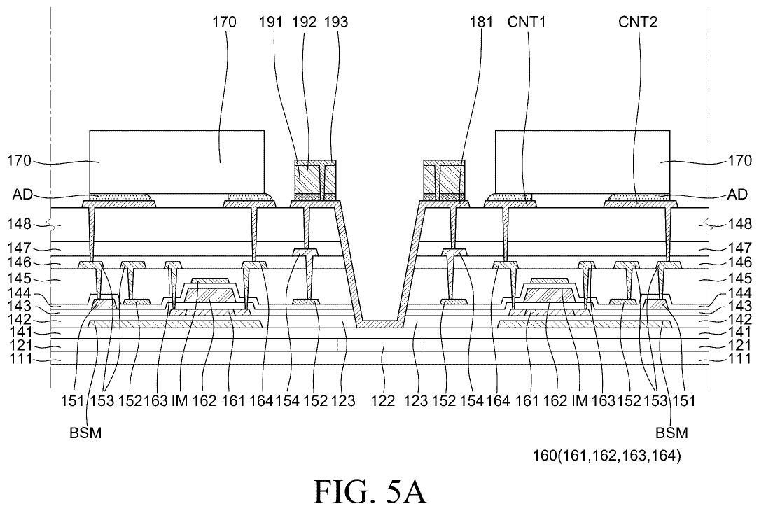

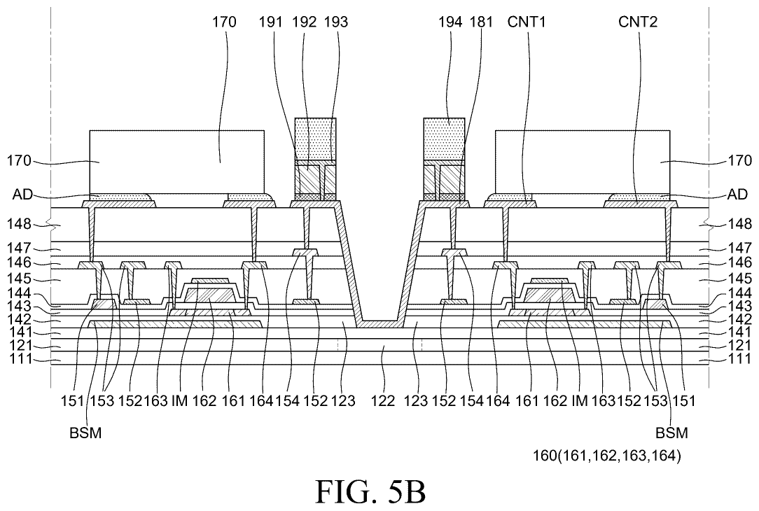

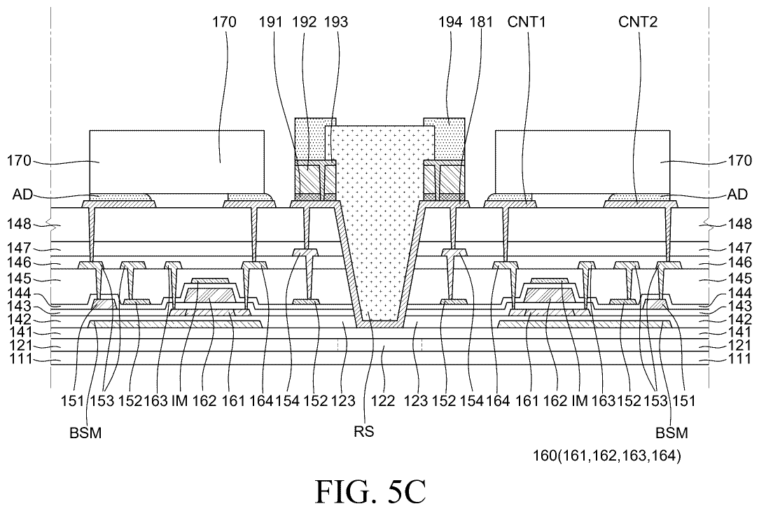

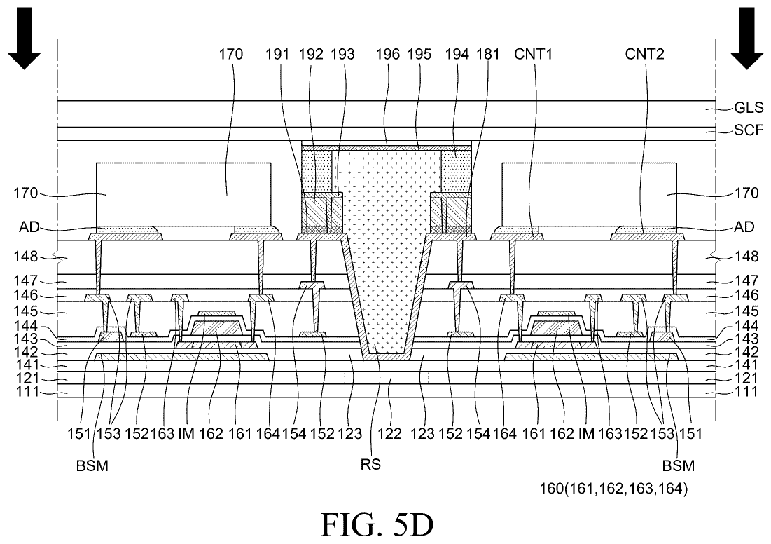

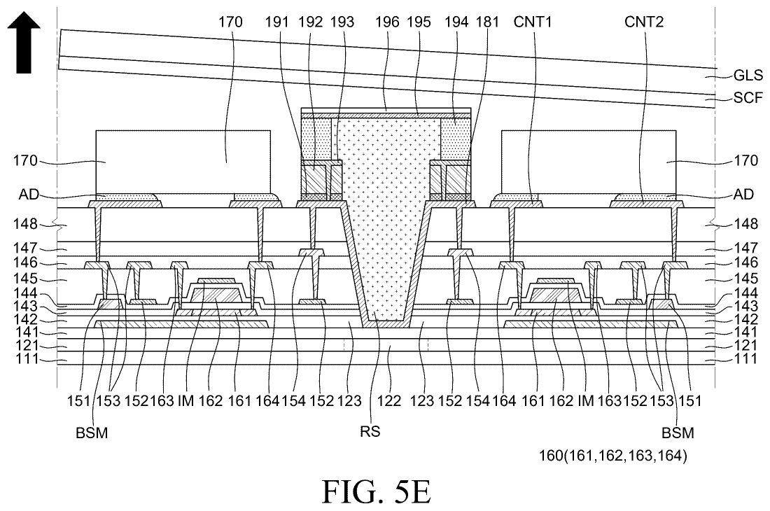

FIGS. 5A to 5E are cross-sectional views illustrating respective steps of a repairing method of a display device according to example embodiments of the present disclosure.

As shown in FIG. 4, a repairing method S100 of a display device according to example embodiments of the present disclosure may include a support pattern and connection electrode formation step S110, an adhesive pattern formation step S120, a sealing step S130, a bonding step S140, and a lift-off step S150.

As shown in FIG. 5A, in the support pattern and connection electrode formation step S110, after forming the first support pattern 191 and the second support pattern 192, the connection electrode 193 is formed.

First, the first support pattern 191 is formed on a flat portion of the connection line 181 by a sputtering or chemical vapor deposition (CVD) process by selecting a single layer or a double layer material from silicon nitride (SiNx), silicon oxide (SiOx), or silicon oxynitride (SiON). Next, the first support pattern is patterned by the photolithography process to form a hole into which the connection electrode 193 is inserted.

Next, the second support pattern 192 is formed on the first support pattern 191 by a spin coating or coating process using photoresist or an acrylic organic material and is patterned by the photolithography process to form a hole in the similar way, and enhances the physical property by the annealing process if necessary.

The formation of the connection electrode 193 begins with forming a metal layer inside and on the surface of the holes of the support patterns 191 and 192 by the sputtering, evaporation, or chemical vapor deposition (CVD) process by selecting a metal, such as molybdenum (Mo), copper (Cu), titanium (Ti), aluminum (Al), chromium (Cr), gold (Au), nickel (Ni), or neodymium (Nd). Next, the metal layer is formed to be a desired pattern using the photolithography and an unnecessary metal layer is removed by a dry or wet etching process to manufacture the connection electrode 193.

As shown in FIG. 5B, in the adhesive pattern formation step S120, first, a conductive adhesive pattern material is applied on the connection electrode 193. The application process is performed to uniformly place the adhesive pattern in an accurate position by utilizing a process, such as screen printing, dispensing, or slit coating. Next, the applied adhesive pattern is subject to a curing process. The curing is performed to enhance the mechanical strength and the electrical connection characteristic of the adhesive pattern by thermal curing or ultraviolet (UV) curing process. The adhesive pattern 194 provides the electrical connection with a high reliability between the connection electrode 193 and the repair line 195 through the adhesive pattern formation step S120.

As shown in FIG. 5C, in the sealing step S130, the sealing layer RS is filled to enclose the upper surface of the connection line 181 and outer peripheries of the plurality of support patterns 191 and 192, the connection electrode 193, and the adhesive pattern 194. To this end, a precise application process, such as spin coating, slit coating, or spray coating, is used to allow the sealing layer to uniformly cover the surface and a clearance of the circuit component. The applied sealing layer is enhanced by the thermal curing or UV curing process. During this process, the sealing layer covers he upper surface of the connection line 181 and side portions of the support patterns 191 and 192 and the adhesive pattern 194, simultaneously, to suppress the permeation of the moisture and the dusts. Further, the sealing layer RS protects the internal circuit from the shocks of the bonding step S140 to be described below to significantly improve the long-term reliability and durability of the display device.

As shown in FIG. 5D, during the bonding step S140, the repair substrate is turned over so that the repair line 195 is disposed to face down. The repair substrate has a structure in which a glass substrate GLS, a sacrificial layer SCF, a cover pattern 196, and a repair line 195 are sequentially laminated. For preparation of bonding, surfaces of the adhesive pattern 194 and the sealing layer RS are cleaned and activated by the cleaning process or the plasma treatment to improve or maximize the adhesive strength. Alignment equipment is used to adjust the position to precisely align the repair line 195 and the adhesive pattern 194 of the repair substrate. During this process, a repair alignment key is utilized to ensure precise position alignment. That is, a repair alignment key RK may be disposed on the active area of the lower substrate 111 to align at least one repair line 195. Specifically, as illustrated in FIG. 2, the repair alignment key RK may be disposed in a plurality of corners of the plate pattern 121. However, the placement of the repair alignment key RK is not limited thereto and may be moved to various positions. Thereafter, the repair line 195 is physically and electrically connected to the adhesive pattern 194 and the sealing layer RS and is coupled thereto under the pressure.

After bonding, conductive balls of the adhesive pattern 194 maintain a solid bonding state while forming the electrical connection with the repair line 195. Simultaneously, the sealing layer RS serves to enclose the repair substrate and the lower substrate to ensure a structural stability. When the bonding process is completed, the mechanical and electrical characteristics of the adhesive pattern 194 are enhanced by the thermal curing or UV curing process.

As shown in FIG. 5E, in the lift-off step S150, the coupling between the sacrificial layer SCF and the glass substrate GLS is selectively separated using a laser energy. First, a focus of the laser light source is precisely aligned to the interface between the sacrificial layer SCF and the glass substrate GLS. Next, the laser beam (for example, excimer laser or the UV laser) is irradiated from the lower surface of the glass substrate GLS to transmit high energy to the sacrificial layer SCF. The laser energy locally heats the sacrificial layer SCF to vaporize or separate the sacrificial layer and the adhesive strength of the sacrificial layer SCF and the glass substrate GLS is weakened during this process.

When the sacrificial layer SCF is separated from the glass substrate GLS by irradiating laser, the separated sacrificial layer SCF is completely removed by a suction device or an anti-static device. When the residual of the sacrificial layer SCF remains even after the laser lift-off process, a chemical cleaning or plasma process is additionally performed to clean the surface. The repair line 195 and the cover pattern 196 are exposed by this process and the physical damage is not caused on the substrate and the line structure during this process. Therefore, the sacrificial layer SCF of the repair substrate is effectively removed to maintain the quality and the function of the repair line 195 and the cover pattern 196 and the reliable electrical connection with a lower connection structure is ensured.

In the repairing method of a display device according to the present disclosure, a repair line which is connected in parallel with a connection line is additionally formed to effectively supplement the disconnection of the connection line. By doing this, the reliability and the stability of the display device may be improved.

A repaired circuit may be protected from external shocks, moisture, and dusts and a long-term durability of the display device may be ensured, by means of the support pattern, the sealing layer, and the cover pattern formed according to the repairing method of a display device according to the present disclosure.

The example embodiments of the present disclosure can also be described as follows:

According to an aspect of the present disclosure, a display device includes a lower substrate which is divided into an active area and a non-active area and is stretchable; a plurality of pixels on the active area of the lower substrate; a plurality of connection lines on the lower substrate and connected to each of the plurality of pixels; and at least one repair line connected in parallel with at least one of the plurality of connection lines.

At least one of the plurality of connection lines which is connected in parallel with the at least one repair line may be electrically disconnected.

A cover pattern may be disposed on an upper surface of the at least one repair line.

The cover pattern may include polyimide (PI) or indium tin oxide (ITO).

Each of the plurality of pixels may include a light emitting element and an upper surface of the cover pattern may be higher than an upper surface of the light emitting element.

The display device may further include at least one support pattern above at least one of the plurality of connection lines; a connection electrode connected to at least one of the plurality of connection lines through a hole formed in the at least one support pattern; and an adhesive pattern electrically connecting the connection electrode and the repair line.

All the at least one repair line, the connection electrode, and the plurality of connection lines may be formed by the same or substantially same material.

The display device may further include a sealing layer between at least one of the plurality of connection lines and the at least one repair line.

A repair alignment key may be disposed on the active area of the lower substrate to align the at least one repair line.

According to another aspect of the present disclosure, a repairing method of a display device including a stretchable substrate, a plurality of pixels on the stretchable substrate, and a plurality of connection lines on the stretchable substrate to be connected to the plurality of pixels, the repairing method includes forming a support pattern and a connection electrode on a connection line which is defective, among the plurality of connection lines; forming an adhesive pattern on the connection electrode; bonding a repair substrate on which a substrate, a sacrificial layer, a cover pattern, and a repair line are sequentially laminated onto the adhesive pattern; and lifting-off the repair substrate to place the cover pattern and the repair line on the adhesive pattern by selectively removing the sacrificial layer.

The repairing method may further include, after the forming of an adhesive pattern, a sealing step of filling a sealing layer so as to enclose outer peripheries of the plurality of connection lines, the support pattern, the connection electrode, and the adhesive pattern.

In the forming of a support pattern and a connection electrode, a first support pattern may be formed on the plurality of connection lines, a second support pattern may be formed on the first support pattern, and a connection electrode may be formed to pass through holes formed in the first support pattern and the second support pattern to be connected to the defective connection line.

In the bonding of the repair substrate onto the adhesive pattern, the repair substrate may be aligned using at least one repair alignment key on the stretchable substrate.

The cover pattern may include polyimide (PI) or indium tin oxide (ITO).

Each of the plurality of pixels may include a light emitting element, and after the lifting-off, an upper surface of the cover pattern may be higher than an upper surface of the light emitting element.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only and not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure may be construed based on the following claims and their equivalents, and all the technical concepts in the equivalent scope thereof should be construed as falling within the scope of the present disclosure.

What is claimed is:

1. A display device, comprising:
a lower substrate which is divided into an active area and a non-active area and is stretchable;
a plurality of pixels on the active area of the lower substrate;
a plurality of connection lines on the lower substrate and connected respectively to the plurality of pixels; and
at least one repair line connected in parallel with at least one of the plurality of connection lines.

2. The display device according to claim 1, wherein the at least one of the plurality of connection lines which is connected in parallel with the at least one repair line is electrically disconnected.

3. The display device according to claim 1, wherein a cover pattern is disposed on an upper surface of the at least one repair line.

4. The display device according to claim 3, wherein the cover pattern includes polyimide (PI) or indium tin oxide (ITO).

5. The display device according to claim 3, wherein each of the plurality of pixels includes a light emitting element, and an upper surface of the cover pattern is disposed higher than an upper surface of the light emitting element.

6. The display device according to claim 5, further comprising:
at least one support pattern above at least one of the plurality of connection lines;
a connection electrode connected to at least one of the plurality of connection lines through a hole formed in the at least one support pattern; and
an adhesive pattern electrically connecting the connection electrode and the repair line.

7. The display device according to claim 6, wherein all the at least one repair line, the connection electrode, and the plurality of connection lines are formed by the same material.

8. The display device according to claim 1, further comprising:
a sealing layer between at least one of the plurality of connection lines and the at least one repair line.

9. The display device according to claim 1, wherein a repair alignment key is disposed on the active area of the lower substrate to align the at least one repair line.

10. A repairing method of a display device including a stretchable substrate, a plurality of pixels on the stretchable substrate, and a plurality of connection lines on the stretchable substrate to be connected to the plurality of pixels, the repairing method comprising:
forming a support pattern and a connection electrode on a defective connection line, among the plurality of connection lines;
forming an adhesive pattern on the connection electrode;
bonding a repair substrate on which a substrate, a sacrificial layer, a cover pattern, and a repair line are sequentially laminated onto the adhesive pattern; and
lifting-off the repair substrate to place the cover pattern and the repair line on the adhesive pattern by selectively removing the sacrificial layer.

11. The repairing method according to claim 10, further comprising:
after the forming of the adhesive pattern,
a sealing step of filling a sealing layer so as to enclose outer peripheries of the plurality of connection lines, the support pattern, the connection electrode, and the adhesive pattern.

12. The repairing method according to claim 10, wherein the forming of the support pattern and the connection electrode includes:
forming a first support pattern on the plurality of connection lines;
forming a second support pattern on the first support pattern; and
forming the connection electrode to pass through holes formed in the first support pattern and the second support pattern to be connected to the defective connection line.

13. The repairing method according to claim 10, wherein the bonding of the repair substrate onto the adhesive pattern includes aligning the repair substrate using at least one repair alignment key on the stretchable substrate.

14. The repairing method according to claim 10, wherein the cover pattern includes polyimide (PI) or indium tin oxide (ITO).

15. The repairing method according to claim 10, wherein:
each of the plurality of pixels includes a light emitting element; and
after the lifting-off of the repair substrate, an upper surface of the cover pattern is disposed higher than an upper surface of the light emitting element.
